(19) United States
(12) Patent Application Publication
(10) Pub. No.: US 2026/0088568 A1
(43) Pub. Date: Mar. 26, 2026

(54) CONNECTOR

(71) Applicant: WNC Corporation, Hsinchu (TW)

(72) Inventors: Lan-Chun YANG, Hsinchu (TW); Huei-Chi WU, Hsinchu (TW); Chia-Ming WANG, Hsinchu (TW)

(21) Appl. No.: 19/297,168

(22) Filed: Aug. 12, 2025

(30) Foreign Application Priority Data
Sep. 2, 2024 (TW) 113133119

(51) Int. Cl. H01R 13/633; H01R 13/627; H01R 13/631; H05K 7/20

(52) U.S. Cl. CPC H01R 13/6335; H01R 13/6275; H01R 13/631; H05K 7/20409

(57) ABSTRACT

A connector suitable for connecting a wire is provided. The connector includes a connector body, an unlocking mechanism, and an extended pull handle. The connector body includes a first side surface, a second side surface, a third side surface, a fourth side surface, and a port, wherein the port is formed on the fourth side surface. The unlocking mechanism includes a first arm, a second arm, and a pull handle, with the first arm connected to one side of the pull handle and the second arm connected to another side of the pull handle. The first arm is disposed on the first side surface, the second arm is disposed on the second side surface, and the pull handle extends only along a first plane parallel to the third side surface. The extended pull handle is connected to the pull handle.

### CROSS REFERENCE TO RELATED APPLICATIONS

This application claims the benefit of priority to Taiwan Patent Application No. 113133119, filed on Sep. 2, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### BACKGROUND OF THE INVENTION

### Field of the Invention

The present disclosure relates to a connector, particularly to a connector for connecting a wire.

### Description of the Related Art

Conventional fiber optic connectors must be designed according to standards regarding their geometric shapes and latch positions. Additionally, fiber optic connectors used for different transmission speeds and requirements must also be designed according to standards. However, due to the significant shape differences in fiber optic connectors, the unlocking mechanism of conventional fiber optic connectors can easily interfere with the fiber optic connector heads, making assembly unachievable.

### BRIEF SUMMARY OF THE INVENTION

The embodiments of the present disclosure aim to solve the problems of the conventional art by providing a connector suitable for connecting a wire. The connector includes a connector body, an unlocking mechanism, and an extended pull handle. The connector body includes a first side surface, a second side surface, a third side surface, a fourth side surface, and a port, wherein the first side surface corresponds to the second side surface, the first side surface connects to one side of the third side surface, the second side surface connects to another side of the third side surface, the port is formed on the fourth side surface, and the wire is suitable for connecting to the port. The unlocking mechanism includes a first arm, a second arm, and a pull handle, the first arm being connected to one side of the pull handle, the second arm being connected to another side of the pull handle, the first arm being disposed on the first side surface, the second arm being disposed on the second side surface, the pull handle extending only along a first plane, the first plane being parallel to the third side surface, and the unlocking mechanism being suitable for moving relative to the connector body between a first position and a second position. The extended pull handle is connected to the pull handle, wherein the extended pull handle extends along the first plane.

In one embodiment, the terminal surface of the fourth side surface is flush with a second plane, and when the unlocking mechanism is in the first position, the first arm does not pass through the second plane, and the second arm does not pass through the second plane.

In one embodiment, the connector body has a first stopper and a first guide formed thereon, the first stopper and the first guide being formed on the third side surface, the first guide extends from the first stopper to the terminal surface of the fourth side surface, and when the unlocking mechanism is in the first position, the pull handle abuts the first stopper, and when the unlocking mechanism moves from the first position to the second position, the pull handle slides along the first guide.

In one embodiment, the first guide includes two guide ribs, the guide ribs being parallel to each other, each guide rib extending from the first stopper to the terminal surface of the fourth side surface.

In one embodiment, the connector body further includes a fifth side surface, a second stopper and a second guide, the fifth side surface corresponding to the third side surface, the second stopper and the second guide are formed on the fifth side surface, the second guide extending from the second stopper to the terminal surface of the fourth side surface.

In one embodiment, the pull handle includes at least one fitting hole, and the extended pull handle fits with the fitting hole.

In another embodiment, the present disclosure provides a connector suitable for connecting a wire. The connector includes a connector body and an unlocking mechanism. The connector body includes a first side surface, a second side surface, a third side surface, a fourth side surface, a fifth side surface, and a port, wherein the first side surface corresponds to the second side surface, the third side surface corresponds to the fifth side surface, the first side surface connects to the third side surface and the fifth side surface, the second side surface connects to the third side surface and the fifth side surface, the port is formed on the fourth side surface, and the wire is suitable for connecting to the port. The unlocking mechanism includes a first arm, a second arm and a pull handle, the first arm being connected to one side of the pull handle, the second arm being connected to another side of the pull handle, the unlocking mechanism being selectively connected to the connector body; in a first combination state, the pull handle abuts the third side surface, and in a second combination state, the pull handle abuts the fifth side surface.

In one embodiment, the connector body has a first stopper and a first guide formed thereon, the first stopper and the first guide being formed on the third side surface, the first guide extending from the first stopper to the terminal surface of the fourth side surface; in the first combination state, the pull handle abuts the first stopper, and when the unlocking mechanism is unlocked from the first combination state, the pull handle slides along the first guide.

In one embodiment, the connector body has a second stopper and a second guide formed thereon, the second stopper and the second guide being formed on the fifth side surface, the second guide extends from the second stopper to the terminal surface of the fourth side surface; in the second combination state, the pull handle abuts the second stopper, and when the unlocking mechanism is unlocked from the second combination state, the pull handle slides along the second guide.

In one embodiment, the connector further includes a connector cover, the connector cover covering at least part of the third side surface of the connector body.

In another embodiment, the present disclosure provides a connector suitable for connecting a wire. The connector includes a connector body, the connector body including a first side surface, a second side surface, a third side surface, a fourth side surface, a fifth side surface, and a port, wherein the first side surface corresponds to the second side surface, the third side surface corresponds to the fifth side surface, the first side surface connects to the third side surface and the fifth side surface, the second side surface connects to the third side surface and the fifth side surface, the port is formed on the fourth side surface, and the wire is suitable for connecting to the port. The connector body has a first stopper, and a first guide formed thereon, the first stopper and the first guide are formed on the third side surface, the first guide extends from the first stopper to the terminal surface of the fourth side surface. The connector body has a second stopper, and a second guide formed thereon, the second stopper and the second guide are formed on the fifth side surface, the second guide extends from the second stopper to the terminal surface of the fourth side surface, wherein the first guide is parallel to the second guide.

In one embodiment, the connector further includes a first unlocking mechanism including a first pull handle, the first pull handle abutting the first guide and being stopped by the first stopper.

In one embodiment, the connector further includes a second unlocking mechanism including a second pull handle, the second pull handle abutting the second guide and being stopped by the second stopper.

In one embodiment, a plurality of heat dissipation fins are formed on the connector cover.

In one embodiment of the present disclosure, the pull handle extends only along a first plane, the first plane being parallel to the third side surface, thereby avoiding interference between the pull handle and the wire. In other words, when applied with fiber optic connector heads with different specifications, the pull handle does not interfere with the fiber optic connector heads. In one embodiment, when the unlocking mechanism is in the first position, the first arm does not pass through the second plane, and the second arm does not pass through the second plane, thereby further preventing the first arm and the second arm from interfering with the wire. The pull handle of the embodiment of the present disclosure can correspondingly contact the third side surface (e.g., the top side with the connector cover) or the fifth side surface (e.g., the bottom side opposite to the connector cover) of the connector body. In other words, the unlocking mechanism of the embodiment of the present disclosure can be installed in different ways to flexibly meet different design requirements.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present invention can be more fully understood by reading the subsequent detailed description and examples with references made to the accompanying drawings, wherein:

FIG. 1 illustrates the usage scenario of the connector according to an embodiment of the present disclosure.

FIG. 2A illustrates a perspective view of the connector according to the first embodiment of the present disclosure, wherein the unlocking mechanism is adapted in a first position relative to the connector body.

FIG. 2B illustrates a perspective view of the connector according to the first embodiment of the present disclosure, wherein the wire is not connected to the connector.

FIG. 3 illustrates a partial structural view of the connector according to the first embodiment of the present disclosure, wherein the unlocking mechanism is adapted in a second position relative to the connector body.

FIG. 4 illustrates another perspective view of the connector according to the first embodiment of the present disclosure.

FIG. 5 illustrates a second unlocking mechanism according to the first embodiment of the present disclosure.

FIG. 6 illustrates a perspective view of the connector according to a second embodiment of the present disclosure.

FIG. 7A illustrates the detailed structure of an unlocking mechanism according to the second embodiment of the present disclosure.

FIG. 7B illustrates the operation of the sliding protrusion according to an embodiment of the present disclosure.

### DETAILED DESCRIPTION OF THE INVENTION

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

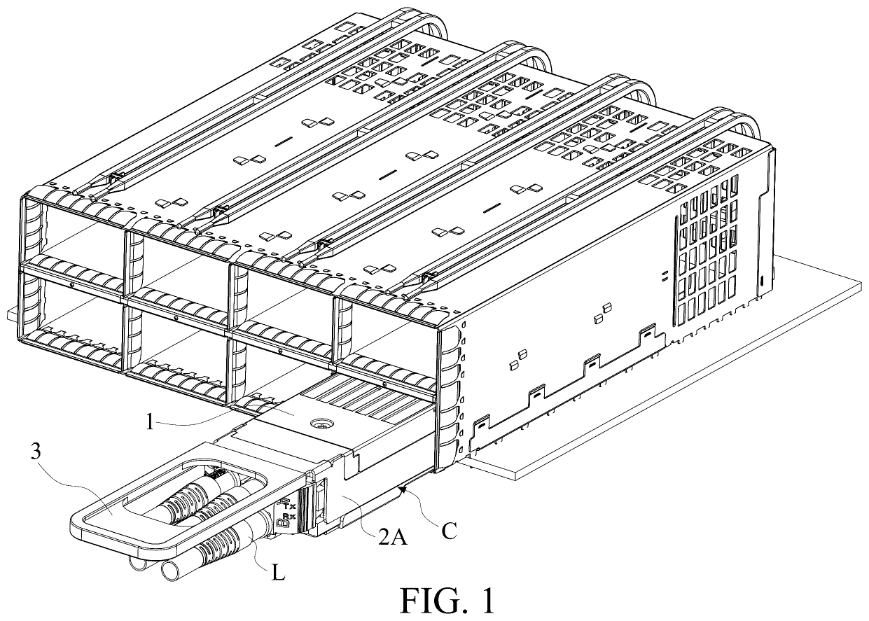

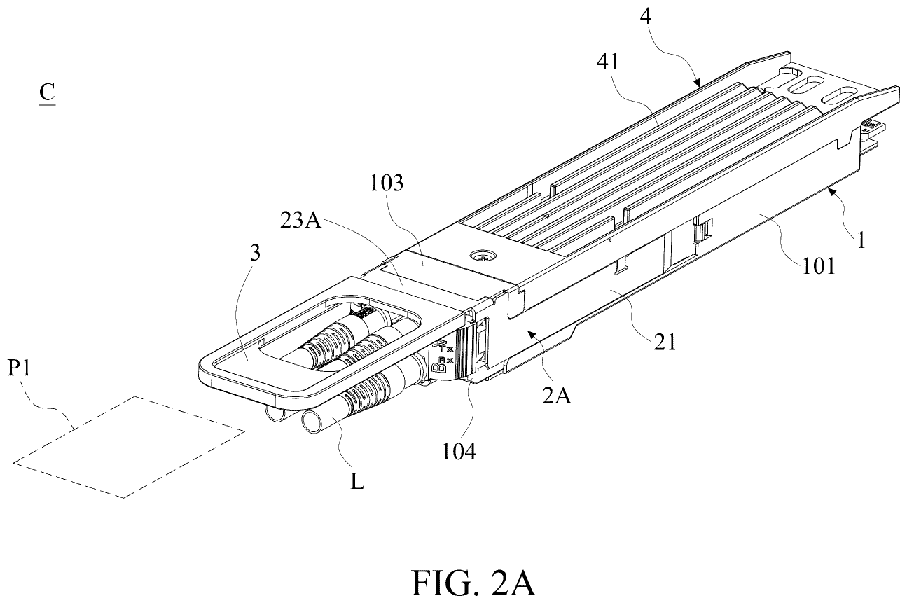

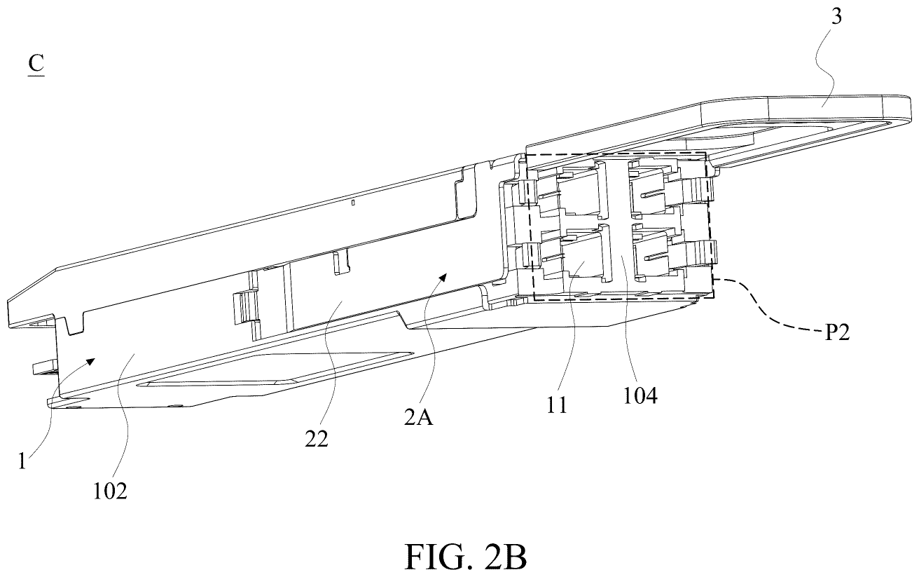

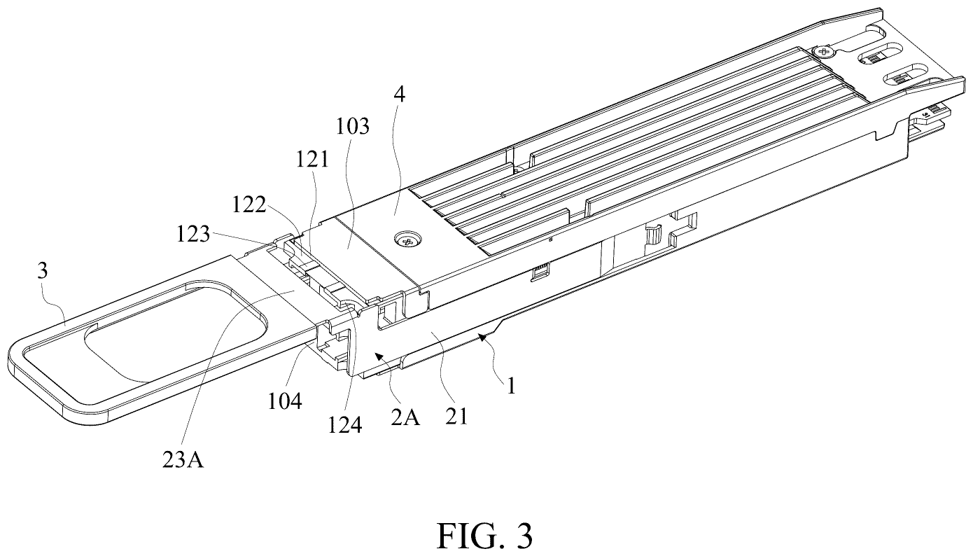

FIG. 1 illustrates the usage scenario of a connector according to an embodiment of the present disclosure. FIG. 2A illustrates a perspective view of the connector according to a first embodiment of the present disclosure, wherein the unlocking mechanism is adapted at a first position relative to the connector body. FIG. 2B illustrates a perspective view of the connector according to the first embodiment of the present disclosure, wherein the wire is not connected to the connector. FIG. 3 illustrates a partial structural view of the connector according to the first embodiment of the present disclosure, wherein the unlocking mechanism is positioned at a second position relative to the connector body. With reference to FIGS. 1, 2A, 2B and 3, the connector C according to the embodiment of the present disclosure is suitable for connecting a wire L. The connector C includes a connector body 1, an unlocking mechanism (first unlocking mechanism) 2A, and an extended pull handle 3. The connector body 1 includes a first side surface 101, a second side surface 102, a third side surface 103, a fourth side surface 104, and a port 11, wherein the first side surface 101 corresponds to the second side surface 102, the first side surface 101 connects to one side of the third side surface 103, the second side surface 102 connects to another side of the third side surface 103, the port 11 is formed on the fourth side surface 104, and the wire L is suitable for connecting to the port 11. The unlocking mechanism 2A includes a first arm 21, a second arm 22, and a pull handle (first pull handle) 23A, wherein the first arm 21 connects to one side of the pull handle 23A, the second arm 22 connects to another side of the pull handle 23A, the first arm 21 is disposed on the first side surface 101, the second arm 22 is disposed on the second side surface 102, the pull handle 23A extends only along a first plane P1, the first plane P1 being parallel to the third side surface 103, and the unlocking mechanism 2A is suitable for moving between a first position (first combination state; FIGS. 2A and 2B) and a second position (FIG. 3) relative to the connector body 1. The extended pull handle 3 connects to the pull handle 23A, wherein the extended pull handle 3 extends along the first plane P1.

With reference to FIGS. 2A and 2B, in one embodiment, a terminal surface of the fourth side surface 104 is flush with a second plane P2. When the unlocking mechanism 2A is in the first position, the first arm 21 does not pass through the second plane P2, and the second arm 22 does not pass through the second plane P2. In one embodiment, the first arm 21 is defined as a component extending along the first side surface 101, and the second arm 22 is defined as a component extending along the second side surface 102.

With reference to FIGS. 2A and 3, in one embodiment, the connector body 1 has a first stopper 121 and a first guide 122 formed thereon, the first stopper 121 and the first guide 122 being formed on the third side surface 103, the first guide 122 extends from the first stopper 121 to the terminal surface of the fourth side surface 104. When the unlocking mechanism 2A is in the first position, the pull handle 23A abuts the first stopper 121; when the unlocking mechanism 2A moves from the first position to the second position, the pull handle 23A slides along the first guide 122.

With reference to FIG. 3, in one embodiment, the first guide 122 includes two guide ribs 123, the guide ribs 123 being parallel to each other, and each guide rib 123 extends from the first stopper 121 to the terminal surface of the fourth side surface 104.

With reference to FIG. 3, in one embodiment, the first guide 122 has arc notches 124 formed on both sides. In one embodiment, the arc notches 124 can prevent interference between the first guide 122 and the wire.

With reference to FIG. 2A, in one embodiment, the connector further includes a connector cover 4, which covers at least a portion of the third side surface 103 of the connector body 1.

With reference to FIG. 2A, in one embodiment, a plurality of heat dissipation fins 41 are formed on the connector cover 4.

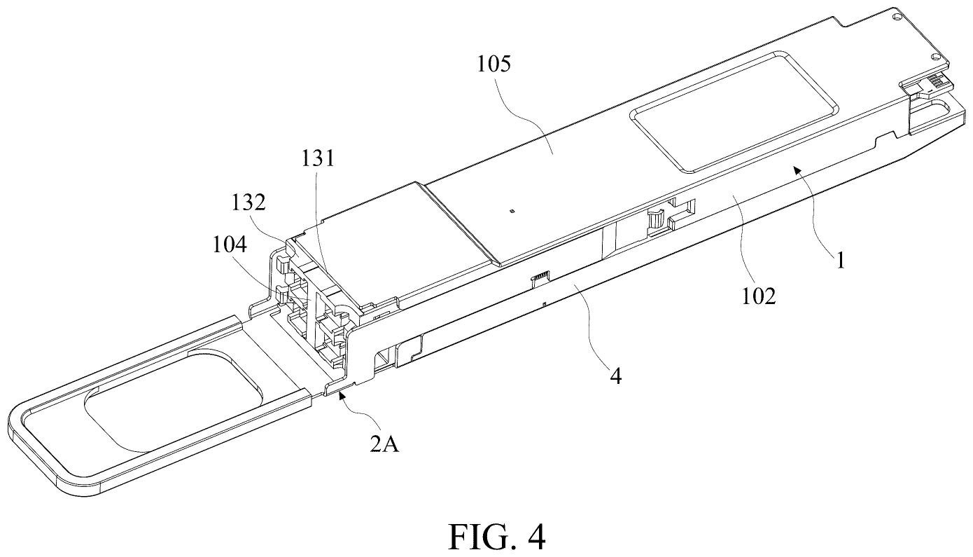

FIG. 4 is another perspective view of the connector according to the first embodiment of the present disclosure. With reference to FIGS. 2A and 4, in one embodiment, the connector body 1 further includes a fifth side surface 105, a second stopper 131, and a second guide 132. The fifth side surface 105 corresponds to the third side surface 103. The second stopper 131 and the second guide 132 are formed on the fifth side surface 105, and the second guide 132 extends from the second stopper 131 to the terminal surface of the fourth side surface 104. In this embodiment, the third side surface 103 corresponds to the fifth side surface 105, the first side surface 101 connects to the third side surface 103 and the fifth side surface 105, and the second side surface 102 connects to the third side surface 103 and the fifth side surface 105. In one embodiment, the unlocking mechanism 2A is selectively connected to the connector body 1. In a first combination state, the pull handle 23A abuts the third side surface 103. In a second combination state, the pull handle 23A abuts the fifth side surface 105 (the second combination state is not shown).

With reference to FIGS. 2A, 3, and 4, in one embodiment, when the unlocking mechanism 2A is unlocked from the first combination state, the pull handle 23A slides along the first guide 122. When the unlocking mechanism 2A is unlocked from the second combination state, the pull handle 23A slides along the second guide 132 (the second combination state is now shown).

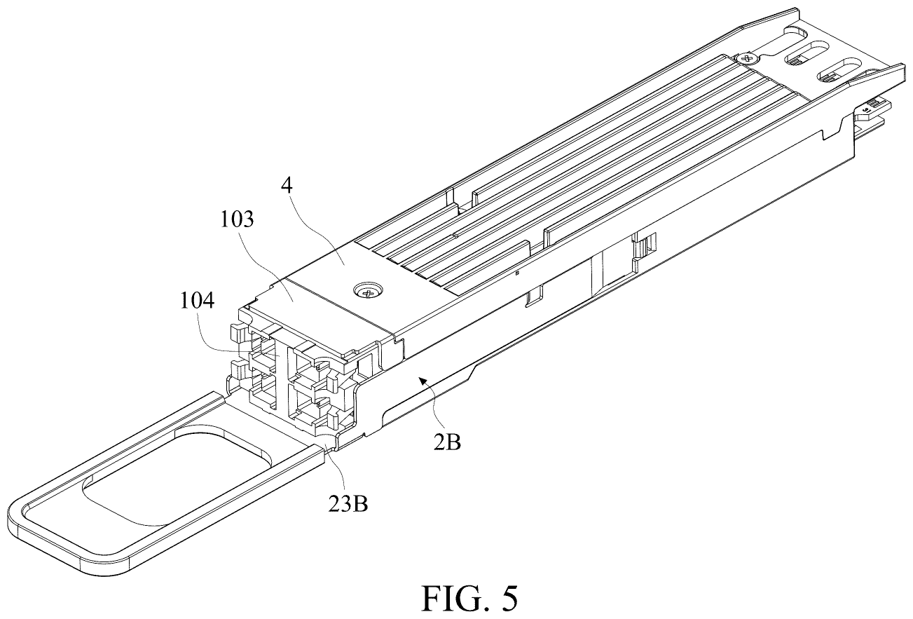

FIG. 5 illustrates the second unlocking mechanism of the first embodiment of the present disclosure. With reference to FIGS. 4 and 5, in one embodiment, the connector C further includes a second unlocking mechanism 2B, including a second pull handle 23B. In a second combination state (FIG. 5), the second pull handle 23B abuts the second guide 132 and is stopped by the second stopper 131.

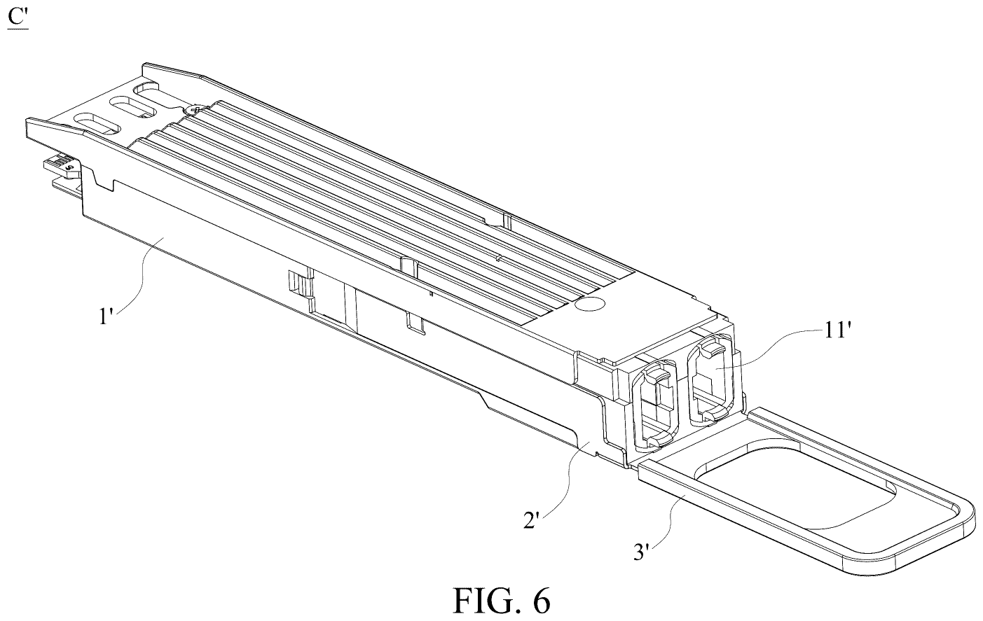

FIG. 6 illustrates a perspective view of the connector according to the second embodiment of the present disclosure. With reference to FIG. 6, in this embodiment, the connector C′ includes a connector body 1′, an unlocking mechanism 2′, and an extended pull handle 3′. The port 11′ is formed on the connector body 1′. The main difference between the second embodiment and the first embodiment is that the specification of the port 11′ in the second embodiment is different from that of the first embodiment.

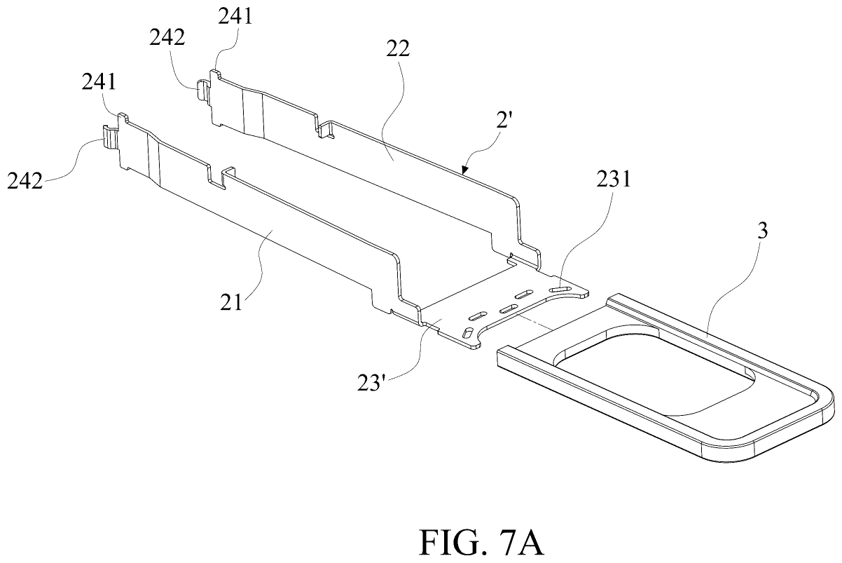

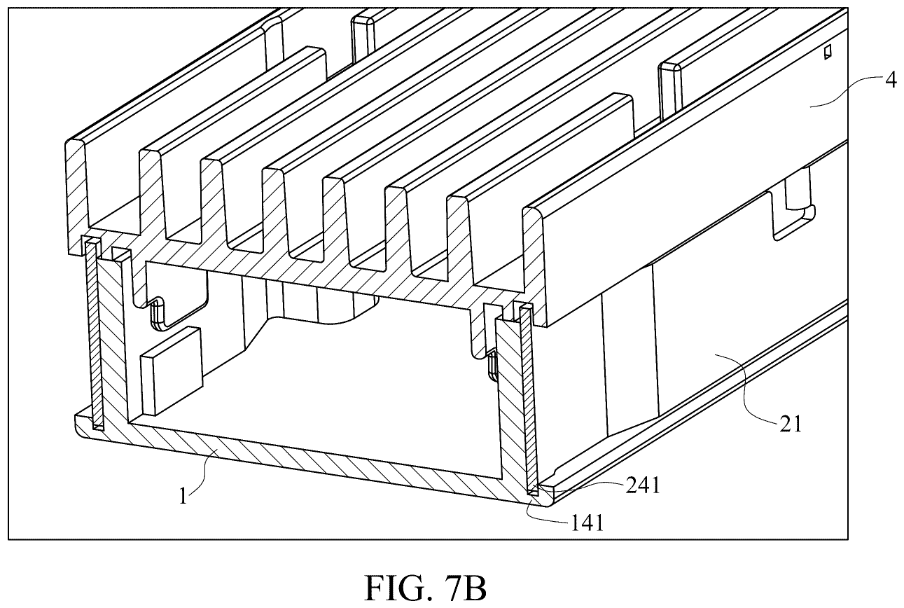

FIG. 7A illustrates the detailed structure of the unlocking mechanism according to the second embodiment of the present disclosure. FIG. 7B illustrates the operation of the sliding protrusion according to the embodiment of the present disclosure. With reference to FIGS. 7A and 7B, in one embodiment, the pull handle 23′ of the unlocking mechanism 2′ includes at least one fitting hole 231, and the extended pull handle 3 fits with the fitting hole 231. In one embodiment, the unlocking mechanism 2′ can be formed by a sheet metal stamping process. The unlocking mechanism 2′ may further include a sliding protrusion 241 and a disengagement portion 242, the sliding protrusion 241 being formed on the first arm 21 and the second arm 22, so as to provide a sliding guide function in the sliding groove 141 on the connector body 1. The disengagement portion 242 is formed on the first arm 21 and the second arm 22 to provide a disengagement function.

In one embodiment of the present disclosure, the pull handle extends only along the first plane, the first plane being parallel to the third side surface, thereby avoiding interference between the pull handle and the wire. In other words, when applied with fiber optic connector heads with different specifications, the pull handle will not interfere with the fiber optic connector heads. In one embodiment, when the unlocking mechanism is in the first position, the first arm does not pass through the second plane, and the second arm does not pass through the second plane, thereby further preventing the first arm and the second arm from interfering with wire. The pull handle of the embodiment of the present disclosure can correspond to the third side surface (e.g., the top surface with the connector cover) or the fifth side surface (e.g., the bottom surface opposite to the connector cover) of the connector body. In other words, the unlocking mechanism of the embodiment of the present disclosure can be installed in different ways to flexibly meet different design requirements.

Although the present disclosure has been disclosed above with specific preferred embodiments, it is not intended to limit the present disclosure. A person skilled in the art can still make some modifications and refinements without departing from the spirit and scope of the present disclosure. Therefore, the protection scope of the present disclosure should be defined by the claims below.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A connector suitable for connecting a wire, the connector comprising:
a connector body including a first side surface, a second side surface, a third side surface, a fourth side surface, and a port, wherein the first side surface corresponds to the second side surface, the first side surface connects to one side of the third side surface, the second side surface connects to another side of the third side surface, the port is formed on the fourth side surface, and the wire being suitable for connecting to the port;
an unlocking mechanism including a first arm, a second arm, and a pull handle, the first arm connects to one side of the pull handle, the second arm connects to another side of the pull handle, the first arm being disposed on the first side surface, the second arm being disposed on the second side surface, the pull handle extending only along a first plane, the first plane being parallel to the third side surface, the unlocking mechanism being suitable for moving relative to the connector body between a first position and a second position; and
an extended pull handle connected to the pull handle, wherein the extended pull handle extends along the first plane.

2. The connector according to claim 1, wherein a terminal surface of the fourth side surface is flush with a second plane, and when the unlocking mechanism is in the first position, the first arm does not pass through the second plane, and the second arm does not pass through the second plane.

3. The connector according to claim 1, wherein the connector body has a first stopper and a first guide formed thereon, the first stopper and the first guide being formed on the third side surface, the first guide extending from the first stopper to a terminal surface of the fourth side surface, and when the unlocking mechanism is in the first position, the pull handle abuts the first stopper, and when the unlocking mechanism moves from the first position to the second position, the pull handle slides along the first guide.

4. The connector according to claim 3, wherein the first guide includes two guide ribs, the guide ribs being parallel to each other, each guide rib extending from the first stopper to the terminal surface of the fourth side surface.

5. The connector according to claim 1, wherein the connector body further includes a fifth side surface, a second stopper, and a second guide, the fifth side surface corresponding to the third side surface, the second stopper and the second guide being formed on the fifth side surface, and the second guide extending from the second stopper to a terminal surface of the fourth side surface.

6. The connector according to claim 1, wherein the pull handle includes at least one fitting hole, and the extended pull handle fits with the fitting hole.

7. A connector suitable for connecting a wire, the connector comprising:
a connector body including a first side surface, a second side surface, a third side surface, a fourth side surface, a fifth side surface, and a port, wherein the first side surface corresponds to the second side surface, the third side surface corresponds to the fifth side surface, the first side surface connects to the third side surface and the fifth side surface, the second side surface connects to the third side surface and the fifth side surface, the port is formed on the fourth side surface, and the wire being suitable for connecting to the port; and
an unlocking mechanism including a first arm, a second arm, and a pull handle, the first arm connects to one side of the pull handle, the second arm connects to another side of the pull handle, the unlocking mechanism being selectively connected to the connector body; in a first combination state, the pull handle abuts the third side surface, and in a second combination state, the pull handle abuts the fifth side surface.

8. The connector according to claim 7, wherein the connector body has a first stopper and a first guide formed thereon, the first stopper and the first guide being formed on the third side surface, the first guide extending from the first stopper to a terminal surface of the fourth side surface, and in the first combination state, the pull handle abuts the first stopper, and when the unlocking mechanism is unlocked from the first combination state, the pull handle slides along the first guide.

9. The connector according to claim 8, wherein the first guide includes two guide ribs, the guide ribs being parallel to each other, each guide rib extending from the first stopper to the terminal surface of the fourth side surface.

10. The connector according to claim 8, wherein the connector body has a second stopper and a second guide formed thereon, the second stopper and the second guide being formed on the fifth side surface, the second guide extending from the second stopper to the terminal surface of the fourth side surface, and in the second combination state, the pull handle abuts the second stopper, and when the unlocking mechanism is unlocked from the second combination state, the pull handle slides along the second guide.

11. The connector according to claim 7, further comprising a connector cover, the connector cover covering at least part of the third side surface of the connector body.

12. A connector suitable for connecting a wire, the connector comprising:
a connector body including a first side surface, a second side surface, a third side surface, a fourth side surface, a fifth side surface, and a port, wherein the first side surface corresponds to the second side surface, the third side surface corresponds to the fifth side surface, the first side surface connects to the third side surface and the fifth side surface, the second side surface connects to the third side surface and the fifth side surface, the port is formed on the fourth side surface, and the wire is suitable for connecting to the port,
wherein the connector body has a first stopper and a first guide formed thereon, the first stopper and the first guide being formed on the third side surface, the first guide extending from the first stopper to a terminal surface of the fourth side surface,
wherein the connector body has a second stopper and a second guide formed thereon, the second stopper and the second guide being formed on the fifth side surface, the second guide extending from the second stopper to the terminal surface of the fourth side surface,
wherein the first guide is parallel to the second guide.

13. The connector according to claim 12, further comprising a connector cover, the connector cover covering at least part of the third side surface of the connector body.

14. The connector according to claim 13, further comprising a first unlocking mechanism including a first pull handle, the first pull handle abuts the first guide and is stopped by the first stopper.

15. The connector according to claim 13, further comprising a second unlocking mechanism, the second unlocking mechanism including a second pull handle, the second pull handle abuts the second guide and is stopped by the second stopper.

16. The connector according to claim 13, wherein a plurality of heat dissipation fins are formed on the connector cover.
